(19) United States
(12) Patent Application Publication
(10) Pub. No.: US 2024/0313015 A1
(43) Pub. Date: Sep. 19, 2024

(54) RADIATION DETECTOR, RADIATION IMAGING SYSTEM, AND METHOD FOR MANUFACTURING RADIATION DETECTOR

(71) Applicant: CANON KABUSHIKI KAISHA, Tokyo (JP)

(72) Inventor: TOSHIYUKI MISHIMA, Kanagawa (JP)

(21) Appl. No.: 18/588,312

(22) Filed: Feb. 27, 2024

(30) Foreign Application Priority Data
Mar. 17, 2023 (JP) 2023-043073

(51) Int. Cl. H01L 27/146; G01T 1/24

(52) U.S. Cl. CPC H01L 27/14618; G01T 1/244; H01L 27/14659

(57) ABSTRACT

A radiation detector includes a detection substrate including a semiconductor layer and a resin layer, and a circuit board. The detection substrate includes a detection region in which a detection element of radiation is provided in the semiconductor layer, and a peripheral region provided outside the detection region. In at least a part of the peripheral region of the detection substrate, the circuit board supports a second main surface opposite to a first main surface of the detection substrate on which the radiation is incident. The resin layer is provided in at least the detection region on at least one of the first main surface and the second main surface of the detection substrate, and a thickness of the resin layer in the detection region is smaller than a thickness of the semiconductor layer in the detection region.

### BACKGROUND

### Field

The present disclosure relates to a radiation detector and the like.

### Description of the Related Art

There is known a radiation detector that obtains a radiation image by receiving radiation with a semiconductor element such as a CMOS image sensor without using a scintillator (wavelength converter). In such a radiation detector, when radiation enters a deep portion of a semiconductor element, crosstalk or secondary electrons are generated, and detection accuracy is reduced, so that the semiconductor layer is thinned.

JP 2019-87640 A discloses a detector in which a thickness of a semiconductor layer in at least a part of a detection region is smaller than a thickness in a peripheral region. It is described that in a detection region of a semiconductor layer, a plurality of grooves is provided on a back surface opposite to a surface on which an energy ray is incident to reduce crosstalk between pixels.

When the semiconductor layer is thinned, the generation of crosstalk and secondary electrons can be reduced, but the mechanical strength of the semiconductor layer is reduced. There is a possibility that the semiconductor layer having a small mechanical strength is damaged by an external force applied during an assembly process or conveyance of the radiation detector.

### SUMMARY

Therefore, there has been a demand for a radiation detector in which generation of crosstalk and secondary electrons due to radiation scattered when passing through a semiconductor layer is suppressed and a decrease in mechanical strength is suppressed.

According to a first aspect of the present invention, a radiation detector includes a detection substrate including a semiconductor layer and a resin layer, and a circuit board. The detection substrate includes a detection region in which a detection element of radiation is provided in the semiconductor layer, and a peripheral region provided outside the detection region. In at least a part of the peripheral region of the detection substrate, the circuit board supports a second main surface opposite to a first main surface of the detection substrate on which the radiation is incident. The resin layer is provided in at least the detection region on at least one of the first main surface and the second main surface of the detection substrate, and a thickness of the resin layer in the detection region is smaller than a thickness of the semiconductor layer in the detection region.

According to a second aspect of the present invention, a radiation detector includes a detection substrate including a semiconductor layer and a layer different from the semiconductor layer, and a circuit board. The detection substrate includes a detection region in which a detection element of radiation is provided in the semiconductor layer, and a peripheral region provided outside the detection region. In at least a part of the peripheral region of the detection substrate, the circuit board supports a second main surface opposite to a first main surface of the detection substrate on which the radiation is incident. The layer is provided in at least the detection region on at least one of the first main surface and the second main surface of the detection substrate. A thickness of the layer in the detection region is smaller than a thickness of the semiconductor layer in the detection region, and the layer has an elastic modulus of 100 MPa or more.

Further features of the present invention will become apparent from the following description of exemplary embodiments with reference to the attached drawings.

### BRIEF DESCRIPTION OF THE DRAWINGS

FIG. 1A is a plan view of a radiation detector 500 according to a first embodiment as viewed from a direction in which radiation is incident.

FIG. 1B is a schematic cross-sectional view of a radiation detector 500 according to the first embodiment.

FIG. 2 is a schematic cross-sectional view of the radiation detector 500 according to the first embodiment in which a resin layer 170 is provided on a first main surface FS side.

FIG. 3 is a schematic cross-sectional view of the radiation detector 500 according to the first embodiment in which the thickness of the resin layer 170 is changed between a detection region PA and a peripheral region PB.

FIG. 4A is a plan view of a radiation detector 510 according to a second embodiment as viewed from a direction in which radiation is incident.

FIG. 4B is a schematic cross-sectional view of the radiation detector 510 according to the second embodiment.

FIG. 5A is a plan view of a radiation detector 520 according to a third embodiment as viewed from a direction in which radiation is incident.

FIG. 5B is a schematic cross-sectional view of the radiation detector 520 according to the third embodiment.

FIG. 6 is a schematic diagram for explaining a radiation imaging system according to a fourth embodiment.

### DESCRIPTION OF THE EMBODIMENTS

A radiation detector according to an embodiment of the present disclosure will be described with reference to the drawings. The following embodiments are examples, and for example, detailed configurations can be appropriately changed and implemented by those skilled in the art without departing from the gist of the present disclosure.

In the drawings referred to in the following description of the embodiment, elements denoted by the same reference numerals have the same functions unless otherwise specified. In the drawings, in a case where a plurality of the same elements is arranged, reference numerals and description thereof may be omitted. In addition, since the drawings may be schematically represented for convenience of illustration and description, shapes, sizes, arrangements, and the like of elements described in the drawings may not strictly coincide with actual objects.

The radiation detected by the radiation detector according to the embodiment may be an electromagnetic wave or a particle beam. The electromagnetic wave may be a light ray such as an infrared ray, a visible ray, or an ultraviolet ray, a radio wave such as a microwave, or an ionizing radiation such as an X-ray or a gamma ray. Examples of the particle beam include an alpha beam, a beta beam, an electron beam, a neutron beam, a proton beam, a heavy ion beam, and an intermediate beam. The structure of the radiation detector, for example, the thickness of the semiconductor layer that converts the radiation into an electrical signal may be appropriately set according to the transmission characteristics and absorption characteristics of the radiation to be detected. In order to prevent the radiation from colliding with air and scattering, the radiation detector of the embodiment described below may be operated in vacuum or in a reduced pressure environment.

### First Embodiment

### Configuration of Radiation Detector

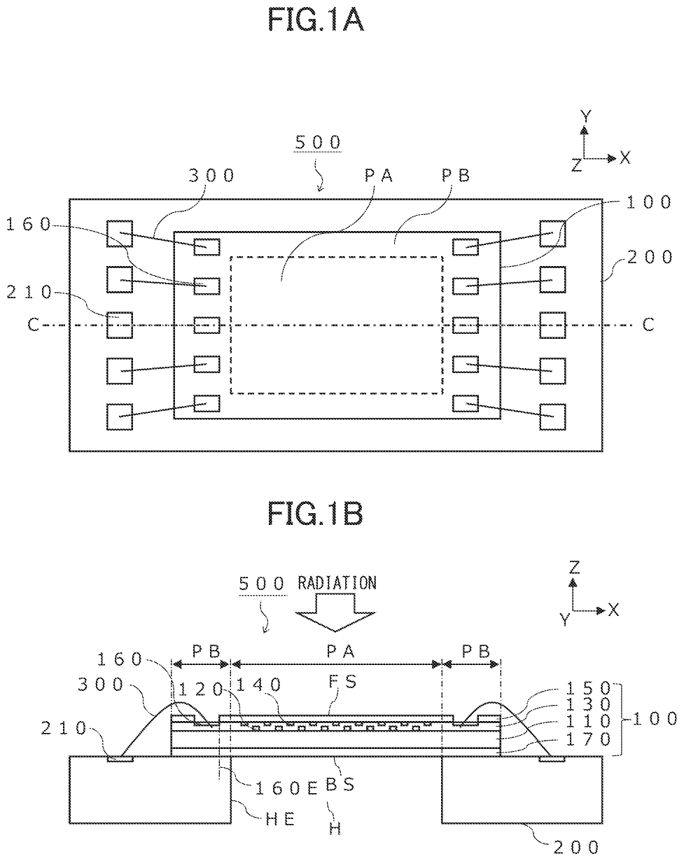

FIG. 1A is a plan view of a radiation detector 500 according to the present embodiment as viewed from a direction in which radiation is incident, and FIG. 1B is a cross-sectional view taken along line C-C in FIG. 1A. The radiation detector 500 includes a detection substrate 100, a circuit board 200, and a connection member 300.

The detection substrate 100 includes a detection region PA as a light receiving unit and a peripheral region PB provided outside the detection region PA. The detection substrate 100 includes a semiconductor layer 110, which is a base material, a detection element 120, an insulating layer 130, a wiring layer 140, a sealing layer 150, and a resin layer 170, but may further include other layers and functional elements. In FIG. 1A, the peripheral region PB indicates a frame shape surrounding the detection region PA, but the shape of the peripheral region PB as a region excluding the detection region PA is not necessarily a frame shape.

In the detection substrate 100, a main surface on a side on which radiation is incident is a first main surface FS, and a main surface on an opposite side is a second main surface BS. Note that, in the following description, a case where the radiation detector 500 is seen through from a direction (Z direction) perpendicular to the main surface of the detection substrate 100 is also referred to as a plan view for convenience.

The circuit board 200 is a board on which an electric circuit that realizes functions described below is mounted. The circuit board 200 is configured to be capable of realizing functions such as supplying a control signal and power to a radiation detection sensor provided on the detection substrate 100, processing a signal output from the detection substrate 100, storing a signal, and transmitting the signal to an external computer or network. As a base material of the circuit board 200, for example, a glass epoxy resin, a paper epoxy resin, a glass polyimide resin, ceramics, or the like is used.

Although an opening H is provided in the circuit board 200, the detection substrate 100 is mounted on the circuit board 200 such that the detection region PA of the detection substrate 100 is located in the opening H of the circuit board 200 in plan view. The opening H is provided to prevent the transmitted radiation from being reflected or scattered by the circuit board 200 and returning to the detection region PA of the detection substrate 100 when the radiation with which the detection region PA is irradiated is transmitted through the detection substrate 100.

The connection member 300 is a member for electrically connecting the circuit board 200 and the detection substrate 100. Specifically, the terminal 210 provided on the circuit board 200 and the terminal 160 provided on the detection substrate 100 are connected by wire bonding using, for example, a wire such as gold or silver, and various control signals, a detected output signal, a power supply, and the like can be transmitted.

The detection substrate 100 will be described in more detail. The semiconductor layer 110, which is a base material of the detection substrate 100, is made of a single crystal layer of silicon, germanium, or the like, or a polycrystalline layer. In the detection region PA of the detection substrate 100, the detection element 120, the insulating layer 130, the wiring layer 140, and the sealing layer 150 are disposed inside or above the semiconductor layer 110 on the first main surface FS side. In the peripheral region PB of the detection substrate 100, terminals 160, alignment marks (not illustrated), peripheral circuits (not illustrated), and the like are arranged. The sealing layer 150 is an inorganic insulating film provided to suppress deterioration of the detection element 120 and the wiring layer 140 due to moisture and oxygen. Specifically, silicon oxide, silicon nitride, silicon oxynitride, silicon carbide, aluminum oxide, or the like can be used. The film thickness of the sealing layer 150 is preferably 200 nm or more from the viewpoint of suppressing moisture and oxygen, and is preferably less than 1000 nm in consideration of the transparency of radiation to the detection element.

The detection region PA as a radiation receiving unit is a region provided with a mechanism for converting electrons generated by incidence of radiation into an output signal. The detection region PA includes a plurality of detection elements 120, a reading circuit, and a wiring layer 140 arranged in a matrix to form an image based on the radiation. The light receiving unit can be said to be a region on which radiation is incident or a detection unit. Each of the plurality of pixels can include a photodiode, similarly to a CMOS image sensor or a CCD. As the photodiode, a compound semiconductor such as CdTe (cadmium telluride) or CdZnTe (cadmium zinc telluride) may be used. In addition, a photon counting principle may be used, and a device such as a single photon avalanche diode (SPAD) may be used.

In the detection region PA, similarly to the CMOS image sensor and the CCD, a circuit of the system that transfers electrons accumulated in the photodiode to the floating diffusion layer via the transfer transistor and reads the potential via the source follower can be provided. A circuit of the system in which the potential of the accumulation portion is directly set to the gate potential of the source follower may be provided without using the transfer transistor.

The peripheral region PB is provided with the terminal 160 for connection with a peripheral circuit such as a drive circuit, a control circuit, a signal processing circuit, and an output circuit, an external power supply, and the like. The drive circuit is a circuit that scans and drives the read circuit of each pixel in the detection region PA. The control circuit is a circuit that controls drive timing of a drive circuit, a signal processing circuit, and the like, and includes a timing generator and the like. The signal processing circuit processes a signal read from the reading circuit of the detection region PA, and includes an amplifier circuit and an AD conversion circuit. The output circuit converts a signal obtained by the signal processing circuit into a predetermined format and outputs the converted signal, and includes a differential transmission circuit.

The semiconductor layer 110 may be a substrate having a uniform thickness as illustrated in FIG. 1B, but may be configured such that the thickness of the detection region PA is smaller than the thickness of the peripheral region PB in order to suppress crosstalk and generation of secondary electrons. In this case, a single substrate may be processed so that the thickness of the portion of the detection region PA becomes thin, or another substrate may be bonded to a peripheral region of the thin substrate to increase the thickness of the semiconductor layer in the peripheral region PB. A plurality of substrates may be bonded by a known method, and then a portion corresponding to the detection region PA may be thinned. For example, in a case where CdTe or CdZnTe is used as a photodiode, the signal reading circuit unit may be constituted by a separately produced CMOS or the like, and the photodiode and the circuit unit may be joined by solder or the like to produce the detection substrate 100.

The thickness of the semiconductor layer 110 in the detection region PA is preferably 100 μm or less in consideration of suppression of crosstalk inside the semiconductor layer. On the other hand, the thickness is preferably 10 μm or more in consideration of improvement in mechanical strength of the detection substrate 100. More desirably, the thickness of the semiconductor layer 110 is preferably 25 μm or more and 75 μm or less.

In the present embodiment, the resin layer 170 is provided on the second main surface BS side of the detection substrate 100. As described above, the opening H is provided at the position corresponding to the detection region PA in the circuit board 200, and the portion of the resin layer 170 arranged in the detection region PA faces the space defined by the opening H. A portion of the resin layer 170 disposed in the peripheral region PB is in contact with the circuit board 200.

In order to prevent the radiation having passed through the detection substrate 100 from being applied to the circuit board 200, when the radiation detector 500 is viewed in a plan view, an opening end HE of the circuit board 200 is disposed on the boundary between the detection region PA and the peripheral region PB or on the outer side (the peripheral region PB side) than the boundary. In addition, the opening end HE (edge of the opening) of the circuit board 200 is preferably provided on the inner side (detection region PA side) of the end 160E of the terminal 160. In other words, it is desirable that the edge (opening end HE) of the opening of the circuit board 200 has a smaller distance to the detection region than the end (end portion 160E) of the terminal 160 on the side closer to the detection region. With the configuration in which the terminal 160 and the circuit board 200 overlap each other in plan view when the radiation detector 500 is viewed in plan view, the detection substrate 100 is less likely to be damaged even if an external force is applied when the connection member 300 is connected to the terminal 160.

The resin layer 170 is, for example, a resin such as an acrylic resin or an epoxy resin, and can transmit radiation without excessive absorption, scattering, and reflection as long as the resin layer has a certain thickness. The lower surface of the resin layer 170 is formed flat so that the second main surface BS of the detection substrate 100 is flat. As the resin layer 170, any resin material such as a thermosetting resin, a UV curable resin, or a two-liquid curable resin can be used. However, in order to suppress generation of thermal stress inside the resin layer and prevent the detection substrate 100 from being excessively warped, a UV curable resin or a two-liquid curable resin is suitably used.

In the thinned semiconductor layer 110 having low mechanical strength, minute polishing scratches generated by back grinding or CMP (chemical mechanical polishing) at the time of thinning remain on the second main surface BS side, and it is difficult to completely remove them. When an external force is applied to the detection substrate 100 at the time of assembling or transporting the radiation detector 500, the detection substrate 100 may be damaged by a minute scratch as a trigger.

According to the present embodiment, by providing the resin layer 170 on the main surface of at least the detection region of the detection substrate 100, there is an effect of improving the mechanical strength of the detection substrate 100 and suppressing damage due to an external force. In addition, the external force applied to the detection substrate 100 can be absorbed and dispersed by the resin layer 170, the external force applied to the semiconductor layer 110 is reduced, and there is an effect of suppressing damage of the detection substrate 100 due to the external force.

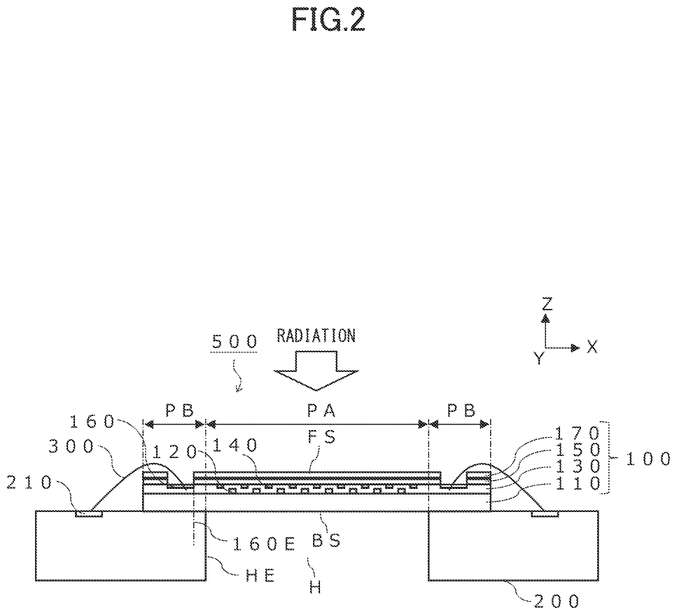

The resin layer 170 is typically provided on the second main surface BS, but may be provided on the first main surface FS side as illustrated in FIG. 2 from the viewpoint of improving the mechanical strength of the detection substrate. When the resin layer 170 is provided on the first main surface FS side, the resin layer 170 can be disposed in a region excluding an opening for connecting the terminal 160 and the connection member 300.

Even when the resin layer 170 is provided on either side of the first main surface FS and the second main surface BS, in order to prevent a decrease in detection accuracy, a resin material not containing metal particles or inorganic particles that inhibit the transmission of radiation more than necessary is used for a portion provided in the detection region PA. The portion of the resin layer 170 provided in the peripheral region PB may contain metal particles or inorganic particles.

In order to efficiently release heat generated by incidence of radiation on the detection substrate 100, it is preferable to use a material having good thermal conductivity for the resin layer 170. For example, thermal conductivity can be improved by using a resin material in which metal particles are dispersed in a binder resin. However, when the metal particles are contained, the transmission of the radiation may be inhibited and the crosstalk may be deteriorated. Therefore, when the metal particles are contained, the thickness of the resin layer disposed in the detection region PA is preferably 5 μm or less. Alternatively, a resin layer containing metal particles may be provided in the peripheral region PB, and a resin layer containing only a binder resin not containing metal particles may be provided in the detection region PA.

The thickness of the resin layer 170 may be 1 μm or more in consideration of covering and smoothing polishing scratches on the second main surface BS side of the semiconductor layer 110, and is preferably 3 μm or more in consideration of absorption and dispersion of external force. On the other hand, if the resin layer 170 becomes too thick, transmission of radiation in the detection region PA is easily hindered, and the internal stress of the resin layer increases, and the warpage of the detection substrate 100 may become too large. Therefore, the thickness of the resin layer 170 in the detection region PA is preferably smaller than the thickness of the semiconductor layer 110 in the detection region PA. More preferably, the detection substrate 100 may be configured such that the thickness of the resin layer 170 in the detection region PA is half or less of the thickness of the semiconductor layer 110 in the detection region PA. For example, in a case where the thickness of the semiconductor layer 110 in the detection region PA is 40 μm, the thickness of the resin layer 170 in the detection region PA is preferably less than 40 μm. In such a case, transmission of radiation is rarely hindered by the resin layer 170, and a problem rarely occurs.

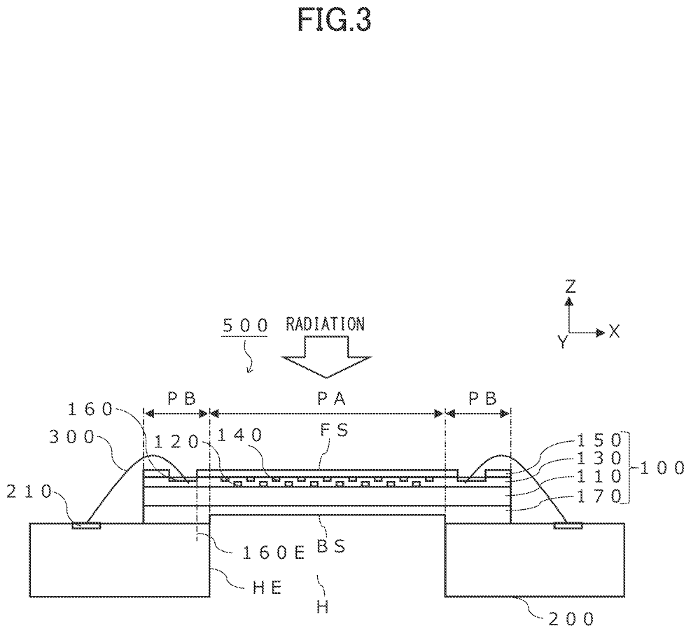

FIG. 1B illustrates an example in which the thickness of the resin layer 170 is made uniform over the entire surface. However, for example, as illustrated in FIG. 3, the thickness of the resin layer 170 may be changed between the detection region PA and the peripheral region PB. Specifically, the thickness of the resin layer in the detection region PA is preferably smaller than the thickness of the resin layer in the peripheral region PB, and the thickness of the resin layer 170 in the detection region PA is preferably half or less of the thickness of the resin layer 170 in the peripheral region PB. For example, the thickness of the peripheral region PB of the resin layer 170 is 30 μm, and the thickness of the detection region PA is 5 μm. A photoresist is formed on the resin layer 170, and only the detection region PA can be thinned by a method such as ashing. In this way, it is possible to improve the mechanical strength and the transparency of the radiation in the detection region PA while greatly improving the mechanical strength of the peripheral region PB of the detection substrate 100.

In addition, when the connection member 300 is connected to the terminal 160, if the resin layer 170 is excessively deformed by application of an external force, there is a possibility that an excessive force is applied to the thinned semiconductor layer 110 and the thinned semiconductor layer is damaged. From the viewpoint of suppressing this, the elastic modulus of the resin layer 170 is preferably 100 MPa or more. More preferably, the elastic modulus of the resin layer 170 is set to 300 MPa or more.

When the resin layer 170 is formed, the resin layer 170 may be formed on the entire surface of a semiconductor wafer (semiconductor substrate) on which a plurality of detection substrates (portions excluding the resin layer 170) is formed, and then the individual detection substrates 100 may be cut by a dicing process. Alternatively, an individual detection substrate may be cut from a wafer on which the resin layer 170 is not formed, and then the resin layer 170 may be formed on each detection substrate. If a semiconductor wafer before being cut or an individual piece after being cut is referred to as a semiconductor substrate, a semiconductor substrate in which the detection element 120 of radiation is provided in the detection region PA of the first main surface FS and the terminal 160 is provided in the peripheral region PB of the first main surface FS is prepared. Then, a resin layer 170 having a thickness smaller than the thickness of the semiconductor substrate in the detection region PA is formed on at least one of the first main surface FS and the second main surface BS at a position overlapping at least the detection region PA as viewed from a direction orthogonal to the first main surface FS.

For example, a UV curable resin or a thermosetting resin is uniformly applied to the second main surface BS of the wafer on which a plurality of detection substrates (portions excluding the resin layer 170) is formed by, for example, a spin coating method, and the UV curable resin or the thermosetting resin is cured by UV or heat to form the resin layer 170. Alternatively, the detection substrate can be cut from the semiconductor wafer on which the resin layer 170 is not formed by dicing, a UV curable resin or a thermosetting resin is applied to the second main surface BS of each detection substrate by, for example, a spray coating method, and cured by UV or heat to form the resin layer 170.

In a dicing step for individually cutting out the detection substrates arranged and formed on the wafer, a disk-shaped cutting tool rotating at a high speed is physically brought into contact and processed. For this reason, chipping or cracks may occur in the edge portion of the semiconductor layer 110 on the first main surface FS side or the second main surface BS side. If the resin layer 170 is not provided, when an external force is applied in a process of assembling the radiation detector 500 or during conveyance, a flaw grows with chipping or a crack as a starting point, and the detection substrate 100 may be damaged. In this regard, according to the present embodiment, since the resin layer 170 is provided on the main surface of the detection substrate 100, even if an external force is applied to the detection substrate 100, the external force is dispersed and is not concentrated locally. Thus, it is possible to suppress the detection substrate 100 from being damaged.

In assembling the radiation detector 500 by mounting the second main surface BS of the detection substrate 100 on the circuit board 200, for example, a hard foreign matter may be interposed between the detection substrate 100 and the circuit board 200. If the resin layer 170 is not provided, there is a possibility that a force is concentrated on a portion in contact with a foreign matter, and the thinned semiconductor layer 110 is damaged. In this regard, according to the present embodiment, since the resin layer 170 is provided on the main surface of the detection substrate 100, the external force is absorbed and dispersed, and the detection substrate 100 can be suppressed from being damaged.

### Method for Manufacturing Radiation Detector

A method for manufacturing the radiation detector 500 according to the embodiment will be described with an example. Here, a case where a DAF (die attach film) is used as the resin layer 170 will be described.

First, a semiconductor wafer is prepared, and the detection element 120 is formed on the side to become the first main surface FS of the detection substrate. An insulating layer 130 is formed on the detection element 120, and a wiring layer 140 is provided inside the insulating layer 130. In addition, a peripheral circuit and a terminal 160 are provided at a position to be the peripheral region PB of the detection substrate. The terminal 160 may be formed as the same layer as the wiring layer 140. Next, a sealing layer 150 for protecting the wiring layer 140 and the detection element 120 from moisture or the like is provided. In this way, a plurality of detection substrates (portions excluding the resin layer 170) are formed on the semiconductor wafer.

A support substrate (not illustrated) such as glass is temporarily attached onto the wafer on which the plurality of detection substrates (portions excluding the resin layer 170) is formed, and then the second main surface BS side of the wafer is thinned to a desired thickness (for example, 40 μm) by back grinding. When the thinning is completed, the wafer on which the support substrate is bonded is bonded to the dicing tape on which the DAF is provided. Then, by dicing the wafer, the portions to be the detection substrates are cut into individual pieces.

By picking up the individual pieces, the DAF provided on the dicing tape is transferred to the surface to be the second main surface BS, and the detection substrate 100 including the resin layer 170 is formed.

The detection substrate 100 is aligned and mounted on the circuit board 200, and the peripheral region PB of the second main surface BS is brought into contact with the circuit board 200 to apply heat. As a result, the resin layer 170 made of the DAF is cured, and the detection substrate 100 and the circuit board 200 can be bonded. In addition, the DAF of the portion not in contact with the circuit board 200 is also cured, and the resin layer 170 having a smooth surface is formed on the second main surface BS side of the detection region PA.

Finally, the terminal 160 and the terminal 210 of the circuit board 200 are connected by wire bonding using a wire such as gold or silver as the connection member 300, whereby the radiation detector 500 is obtained.

According to the present embodiment, since the mechanical strength of the detection substrate 100 is improved by providing the resin layer 170 on the main surface of the detection substrate 100, it is possible to suppress damage to the detection substrate 100 even if an external force is applied during the assembly process or conveyance of the radiation detector 500. As a result, the yield and reliability when mounting the detection substrate are improved.

### Second Embodiment

A radiation detector 510 according to the second embodiment will be described. Elements common to the first embodiment are denoted by the same reference numerals in the drawings. In addition, the description of matters having common description contents may be simplified or omitted.

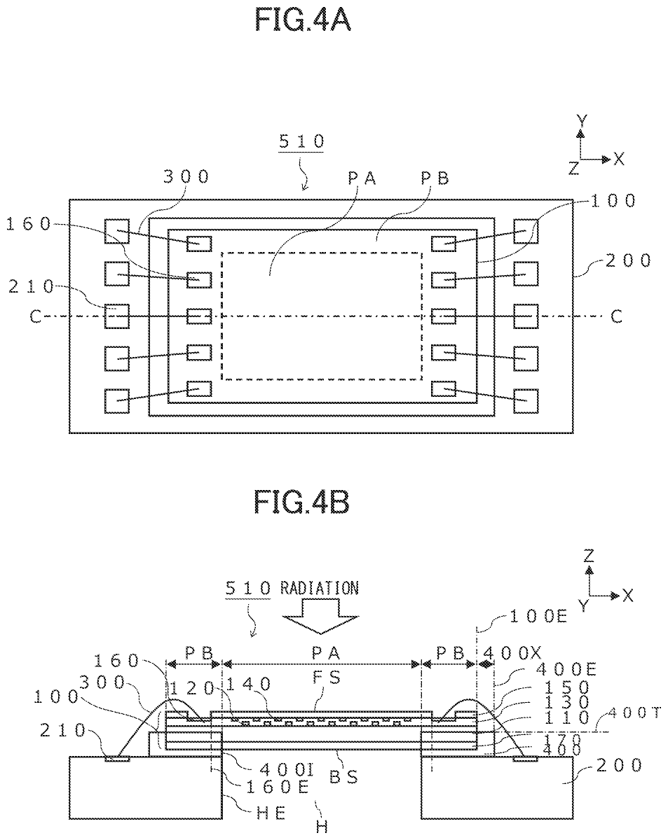

FIG. 4A is a plan view of the radiation detector 510 according to the present embodiment as viewed from a direction in which radiation is incident, and FIG. 4B is a cross-sectional view taken along line C-C of FIG. 4A. The radiation detector 510 is the same as that of the first embodiment in including the detection substrate 100, the circuit board 200, and the connection member 300, but is different in that an adhesive layer 400 is provided between the detection substrate 100 and the circuit board 200.

The resin layer 170 is typically provided on the second main surface BS as illustrated in FIG. 4B, but may be provided on the first main surface FS side from the viewpoint of improving the mechanical strength of the detection substrate. When the resin layer 170 is provided on the first main surface FS side, the resin layer 170 is disposed in a region excluding an opening for connecting the terminal 160 and the connection member 300.

As illustrated in FIG. 4A, the adhesive layer 400 protrudes to a region outside the detection substrate 100 in plan view. As illustrated in FIG. 4B, a part of the side surface of the detection substrate 100 is covered with the adhesive layer 400. That is, the outer end 400E of the adhesive layer 400 protrudes outward from the outer surface 100E of the detection substrate 100, and the edge of the upper surface 400T of the adhesive layer 400 in the protruding portion 400X is in contact with the outer surface 100E of the detection substrate 100.

As described above, by dicing the thinned wafer, chipping and cracks are formed at the end of the semiconductor layer 110, and the wafer is mechanically brittle and easily damaged. If the resin layer 170 is not provided, when an external force is applied in a process of assembling the radiation detector 510 or during conveyance, a flaw grows with chipping or a crack as a starting point, and the detection substrate 100 may be damaged. In this regard, according to the present embodiment, since the resin layer 170 is provided on the main surface of the detection substrate 100, even if an external force is applied to the detection substrate 100, the external force is dispersed and is not concentrated locally. Thus, it is possible to suppress the detection substrate 100 from being damaged.

Furthermore, in the present embodiment, the mechanical strength can be improved by covering at least a part of the end surface (side surface) of the detection substrate 100 with the adhesive layer 400. Of course, the entire end surface (side surface) of the detection substrate 100 may be covered with the adhesive layer 400.

The inner end 400I of the adhesive layer 400 is preferably disposed outside (on the peripheral region PB side) the boundary between the detection region PA and the peripheral region PB. In particular, in a case where metal particles or inorganic particles are contained in the adhesive layer 400 to improve thermal conductivity and suppress heat accumulation in the detection substrate 100, when radiation having transmitted the detection region PA is scattered or reflected by the adhesive layer 400, noise is generated. Therefore, it is preferable to dispose the adhesive layer 400 at a position not overlapping the detection region PA in plan view.

In addition, the inner end 400I of the adhesive layer 400 is preferably provided on the inner side (detection region PA side) of the inner end 160E of the terminal 160. In other words, an end (inner end 400I) of the adhesive layer 400 on a side closer to the detection region PA has a smaller distance to the detection region PA than an end (end portion 160E) of the terminal 160 on a side closer to the detection region PA. By disposing the adhesive layer 400 at a position overlapping the terminal 160 in plan view, it is possible to eliminate a gap between the second main surface BS of the detection substrate 100 and the circuit board 200 in the peripheral region PB. As a result, even if an external force is applied when the connection member 300 is connected to the terminal 160, it is possible to suppress damage to the thinned detection substrate 100 (semiconductor layer 110).

As the adhesive layer 400, any resin material such as a thermosetting resin, a UV curable resin, or a two-liquid curable resin can be used, but since the adhesive layer 400 is disposed between the detection substrate 100 and the circuit board 200, it is difficult to irradiate UV. Therefore, a thermosetting resin is suitably used as the adhesive layer 400. As described above, in order to efficiently release heat generated by incidence of radiation on the detection substrate 100, it is preferable to use a material having good thermal conductivity for the adhesive layer 400. For example, by using a resin material in which metal particles are dispersed in a binder resin, the thermal conductivity of the adhesive layer 400 can be improved. From the viewpoint of thermal conductivity, the thickness of the adhesive layer 400 disposed between the detection substrate 100 and the circuit board 200 is preferably 50 μm or less.

In assembling the radiation detector 510 by mounting the second main surface BS of the detection substrate 100 on the circuit board 200, for example, a hard foreign matter may be interposed between the detection substrate 100 and the circuit board 200. If the resin layer 170 is not provided, there is a possibility that a force is concentrated on a portion in contact with a foreign matter, and the thinned semiconductor layer 110 is damaged. In this regard, according to the present embodiment, since the resin layer 170 is provided on the main surface of the detection substrate 100, the external force is absorbed and dispersed, and the detection substrate 100 can be suppressed from being damaged.

Furthermore, in the present embodiment, the radiation detector 510 can be assembled using a resin having plasticity before curing, such as a die attach film (DAF), as the adhesive layer 400. In that case, the adhesive layer 400 is solidified after the detection substrate 100 and the circuit board 200 are aligned in a state where the adhesive layer 400 has plasticity. Even if the foreign matter is sandwiched between the detection substrate 100 and the circuit board 200, the adhesive layer 400 can be solidified after the adhesive layer 400 is deformed so as to wrap the foreign matter. As a result, a structure in which the external force applied to the detection substrate 100 is dispersed without being concentrated on the place where the foreign matter exists is formed. Thus, it is possible to suppress the detection substrate 100 from being damaged by the external force.

In addition, when the connection member 300 is connected to the terminal 160, if the adhesive layer 400 is excessively deformed by an external force, there is a possibility that an excessive force is applied to the thinned semiconductor layer 110 and the semiconductor layer is damaged. From the viewpoint of suppressing this, the elastic modulus of the adhesive layer 400 is preferably 100 MPa or more. More preferably, the elastic modulus of the adhesive layer 400 is set to 300 MPa or more.

When the detection substrate 100 is attached to the circuit board 200 in an inclined manner, the incident angle of the radiation with which the detection substrate 100 is irradiated is inclined, so that reflection or refraction occurs. Thus, there is a possibility that the detection accuracy is deteriorated. Therefore, it is preferable to disperse a spacer having a desired particle diameter in the resin constituting the adhesive layer 400 so that the thickness of the adhesive layer between the detection substrate 100 and the circuit board 200 becomes uniform. If the spacer is used, the thickness of the adhesive layer 400 can be controlled to be a uniform predetermined thickness in the bonding surface, so that the distance between the circuit board 200 and the detection substrate 100 is defined, and the detection substrate 100 can be fixed such that the main surface is parallel to the circuit board 200. That is, the detection substrate 100 can be fixed such that radiation is incident on the detection region PA at a predetermined angle.

The adhesive layer 400 can be formed on the circuit board 200 using a coating technique such as a dispenser or screen printing. The adhesive layer 400 is formed in advance such that the outer end 400E protrudes outward from the outer surface 100E of the detection substrate 100. The detection substrate 100 is aligned with the circuit board 200 to which the adhesive layer 400 is applied, and the detection substrate 100 is mounted on the circuit board 200. Thereafter, when a load is applied from the detection substrate 100 side, the detection substrate 100 sinks into the adhesive layer 400, and the edge of the upper surface 400T of the adhesive layer 400 in the protruding portion 400X is in contact with the outer surface 100E of the detection substrate 100. The adhesive layer 400 is cured using a curing method corresponding to the type of adhesive while maintaining the position and posture in this state. Thereafter, the terminal 210 of the circuit board 200 and the terminal 160 of the detection substrate 100 are electrically connected by the connection member 300, whereby the radiation detector 510 of the present embodiment is obtained.

Also in the present embodiment, since the mechanical strength of the detection substrate 100 is improved by providing the resin layer 170 on the main surface of the detection substrate 100, it is possible to suppress damage to the detection substrate 100 even if an external force is applied during the assembly process or conveyance of the radiation detector 510.

Furthermore, since the adhesive layer 400 covers at least a part of the end surface of the detection substrate 100, damage to the end surface of the detection substrate 100 when an external force is applied can be suppressed as compared with the first embodiment. In addition, it is also possible to suppress damage to the detection substrate 100 that occurs when the connection member 300 is connected to the terminal 160. As a result, the yield and reliability of the detection substrate are further improved.

### Third Embodiment

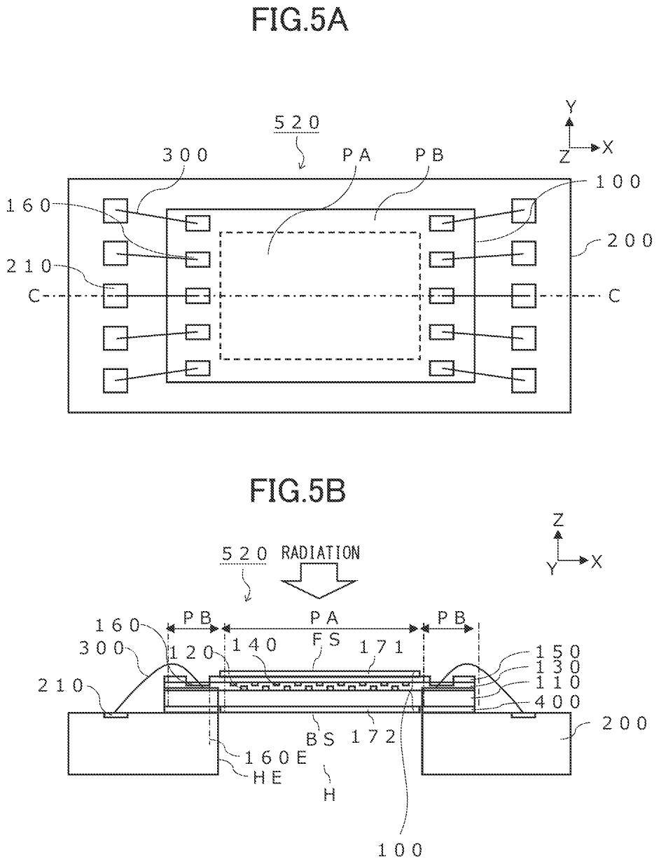

A radiation detector 520 according to the third embodiment will be described with reference to FIGS. 5A and 5B. Elements common to the first embodiment or the second embodiment are denoted by the same reference numerals in the drawings. In addition, the description of matters having common description contents may be simplified or omitted.

FIG. 5A is a plan view of the radiation detector 520 according to the present embodiment as viewed from a direction in which radiation is incident, and FIG. 5B is a cross-sectional view taken along line C-C of FIG. 5A. The radiation detector 520 is common to the second embodiment in including the detection substrate 100, the circuit board 200, the connection member 300, and the adhesive layer 400, but is different in that a resin layer is provided on both main surfaces of the detection substrate 100. As illustrated in FIG. 5B, the first resin layer 171 is disposed in the detection region PA of the first main surface FS of the detection substrate 100, and the second resin layer 172 is disposed in the detection region PA of the second main surface BS.

The materials and thickness ranges of the first resin layer 171 and the second resin layer 172 are the same as those of the resin layer 170 in the first embodiment. In a case where the resin layer is provided on only one of the first main surface FS and the second main surface BS, when radiation is incident on the detection substrate 100 and the temperature of the detection substrate 100 rises, warpage may occur in the detection substrate 100 due to a difference in linear expansion coefficient between the semiconductor layer 110 and the resin layer 170. In the present embodiment, in consideration of reducing damage of the detection substrate 100 due to warpage, it is preferable that the first resin layer 171 and the second resin layer 172 have substantially the same thickness and substantially the same area, and are disposed so as to substantially overlap each other in plan view. More desirably, the first resin layer 171 and the second resin layer 172 have the same thickness and the same area, and are disposed so as to overlap each other in plan view.

The material and the thickness range of the adhesive layer 400 are the same as those of the adhesive layer 400 in the second embodiment. However, in the present embodiment, as shown in FIG. 5B, the adhesive layer 400 is disposed apart from the second resin layer 172 so that the adhesive layer 400 does not interfere with the second resin layer 172.

Also in the present embodiment, a material having good thermal conductivity such as a resin containing metal particles can be used as the adhesive layer 400. When the second resin layer 172 having low thermal conductivity (for example, a resin layer not containing metal particles) is disposed between the semiconductor layer 110 and the adhesive layer 400, heat cannot be effectively released to the circuit board 200 via the adhesive layer 400, and the cooling ability of the detection substrate 100 is deteriorated. In the present embodiment, on the second main surface BS, the second resin layer 172 is not provided in the peripheral region PB, and the semiconductor layer 110 and the adhesive layer 400 are in contact with each other. As a result, the heat generated in the detection substrate 100 by the incidence of the radiation can be efficiently conducted to the circuit board 200 side.

Note that, in the example illustrated in FIGS. 5A and 5B, the adhesive layer 400 does not protrude outward from the detection substrate 100, but as in the second embodiment, the adhesive layer 400 may protrude outward from the detection substrate 100 to cover at least a part of the end side surface of the detection substrate 100.

A method of forming the adhesive layer 400 on the circuit board 200, a method of bonding the detection substrate 100 to the circuit board 200, and a method of electrically connecting terminals by a connection member can be performed in the same manner as in the second embodiment. As described above, the radiation detector 520 of the present embodiment is obtained.

Also in the present embodiment, since the mechanical strength of the detection substrate 100 is improved by providing the resin layer on the main surface of the detection substrate 100, it is possible to suppress damage to the detection substrate 100 even if an external force is applied during the assembly process or conveyance of the radiation detector 520.

Furthermore, in the present embodiment, by providing the resin layers on both main surfaces of the detection substrate 100 in the detection region PA where the thickness of the semiconductor layer 110 is small, the mechanical strength can be effectively enhanced. Since the resin layers are provided on both main surfaces, it is possible to suppress occurrence of warpage in the detection substrate 100 due to a difference in linear expansion coefficient between the semiconductor layer 110 and the resin layer when radiation is incident and heat is generated. Therefore, as compared with the first and second embodiments, it is possible to prevent a decrease in detection accuracy and destruction of the detection substrate 100 due to warpage caused by heat generation.

In addition, by bringing the semiconductor layer 110 and the adhesive layer 400 into contact with each other without providing the second resin layer 172 in the peripheral region PB, heat of the detection substrate 100 can be efficiently discharged to the circuit board 200 via the adhesive layer. As described above, according to the present embodiment, it is possible to improve the yield and reliability of the detection substrate.

### Fourth Embodiment

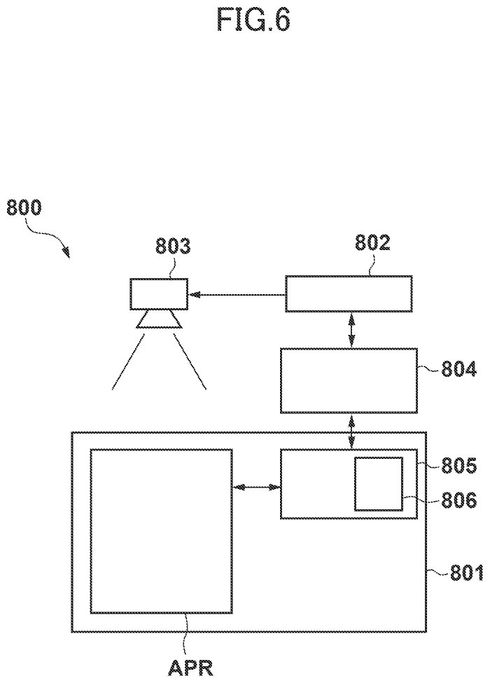

As the fourth embodiment, a radiation imaging device 801 including a radiation detector according to any one of the first to third embodiments described above and a radiation imaging system 800 using the radiation imaging device will be described with reference to FIG. 6. A radiation detector APR illustrated in FIG. 6 is any of the radiation detector 500 according to the first embodiment, the radiation detector 510 according to the second embodiment, and the radiation detector 520 according to the third embodiment.

The radiation imaging system 800 is configured to electrically capture an optical image formed by radiation to obtain an electrical radiation image (that is, the radiation image data). The radiation imaging system 800 includes, for example, a radiation imaging device 801, an exposure control unit 802, a radiation source 803, and a computer 804. The radiation imaging system 800 can display a captured radiation image on a display device (not illustrated) or transmit radiation image data to the outside via a communication device (not illustrated). The radiation imaging system 800 can be suitably used in fields such as medical image diagnosis and non-destructive inspection.

The radiation source 803 for emitting radiation starts emitting radiation in accordance with an exposure command from the exposure control unit 802. The radiation emitted from the radiation source 803 is emitted to the radiation imaging device 801 through a subject (not illustrated). The radiation source 803 stops radiation in accordance with the stop command from the exposure control unit 802.

The radiation imaging device 801 includes a radiation detector APR, a control unit 805 for controlling the radiation detector APR, and a signal processing unit 806 for processing a signal output from the radiation detector APR.

For example, in a case where the signal output from the radiation detector APR is an analog signal, the signal processing unit 806 can perform A/D conversion on the analog signal and output a digital signal to the computer 804 as radiation image data. Furthermore, the signal processing unit 806 may generate a stop signal for stopping irradiation of radiation from the radiation source 803 on the basis of a signal output from the radiation detector APR, for example. The stop signal is supplied to the exposure control unit 802 via the computer 804, and the exposure control unit 802 sends a stop command to the radiation source 803 in response to the stop signal.

The control unit 805 can be configured by, for example, a programmable logic device (PLD) such as a field programmable gate array (FPGA). Alternatively, the control unit 805 can also be configured by an application specific integrated circuit (ASIC) or a general-purpose computer in which a program is incorporated. Furthermore, it can be configured by a combination of all or one part described above.

Furthermore, although the signal processing unit 806 is illustrated as being disposed in the control unit 805 or being a part of the function of the control unit 805, it is not limited thereto. The control unit 805 and the signal processing unit 806 may be configured separately. Furthermore, the signal processing unit 806 may be disposed separately from the radiation imaging device 801. For example, the computer 804 may have the function of the signal processing unit 806. Therefore, the signal processing unit 806 can be included in the radiation imaging system 800 as a signal processing device that processes a signal output from the radiation imaging device 801.

The computer 804 can perform control of the radiation imaging device 801 and the exposure control unit 802, and processing for receiving radiation image data from the radiation imaging device 801 and displaying the radiation image data as a radiation image. In addition, the computer 804 can function as an input unit for the user to input conditions for capturing a radiation image.

As an example of the sequence, the exposure control unit 802 includes an exposure switch. When the exposure switch is turned on by the user, the exposure control unit sends an exposure command to the radiation source 803 and also sends a start notification indicating the start of radiation emission to the computer 804. The computer 804 that has received the start notification notifies the control unit 805 of the radiation imaging device 801 of the start of irradiation of radiation in response to the start notification. In response to this, the control unit 805 causes the radiation detector APR to generate a signal corresponding to the incident radiation.

The radiation imaging device of the present embodiment and the radiation imaging system using the radiation imaging device detect radiation using the radiation detector APR. Since the resin layer is provided on the main surface of the detection substrate, the radiation detector APR has high mechanical strength, and the reliability of the radiation imaging device and the radiation imaging system using the radiation imaging device can be improved.

### OTHER EMBODIMENTS

A transmission electron microscope (TEM) system may be configured as a radiation imaging system in which the radiation detector according to any one of the first to third embodiments is incorporated. In this case, since the resin layer is provided on the main surface of the detection substrate of the radiation detector, the mechanical strength of the radiation detector is high. Therefore, reliability of a transmission electron microscope (TEM) system can be improved.

Furthermore, not only the transmission electron microscope (TEM) but also, for example, a scanning electron microscope (SEM) and a scanning transmission electron microscope (STEM) may be configured. Furthermore, for example, an electron microscope having a processing function such as ion beam milling or ion beam induced deposition (IBID), or a dual-beam electron microscope having a focused ion beam (FIB) such as FIB-SEM may be configured.

Note that the present disclosure is not limited to the embodiments described above, and many modifications can be made within the technical idea of the present disclosure. For example, all or some of the different embodiments described above may be combined and implemented.

According to the present invention, it is possible to provide a radiation detector in which generation of crosstalk and secondary electrons due to radiation scattered when passing through a semiconductor layer is suppressed, and a decrease in mechanical strength is suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-43073, filed Mar. 17, 2023, which is hereby incorporated by reference herein in its entirety.

What is claimed is:

1. A radiation detector comprising:
a detection substrate including a semiconductor layer and a resin layer; and a circuit board,
wherein the detection substrate includes a detection region in which a detection element of radiation is provided in the semiconductor layer, and a peripheral region provided outside the detection region,
in at least a part of the peripheral region of the detection substrate, the circuit board supports a second main surface opposite to a first main surface of the detection substrate on which the radiation is incident,
the resin layer is provided in at least the detection region on at least one of the first main surface and the second main surface of the detection substrate, and
a thickness of the resin layer in the detection region is smaller than a thickness of the semiconductor layer in the detection region.

2. The radiation detector according to claim 1, wherein
the thickness of the semiconductor layer in the detection region is 10 μm or more and 100 μm or less.

3. The radiation detector according to claim 1,
wherein the thickness of the resin layer in the detection region is 1 μm or more and half or less of the thickness of the semiconductor layer in the detection region.

4. The radiation detector according to claim 1,
wherein the resin layer is provided in both the detection region and the peripheral region, and the thickness of the resin layer in the detection region is smaller than the thickness of the resin layer in the peripheral region.

5. The radiation detector according to claim 1,
wherein the resin layer is provided on both the first main surface and the second main surface of the detection substrate in the detection region.

6. The radiation detector according to claim 1,
wherein the resin layer has an elastic modulus of 100 MPa or more.

7. The radiation detector according to claim 1,
wherein the detection substrate is fixed to the circuit board via an adhesive layer in the peripheral region.

8. The radiation detector according to claim 7,
wherein the adhesive layer covers at least a part of a side surface of the detection substrate.

9. The radiation detector according to claim 7,
wherein the adhesive layer includes a resin material in which metal particles are dispersed.

10. The radiation detector according to claim 7,
wherein the adhesive layer includes a spacer configured to define a distance between the detection substrate and the circuit board.

11. The radiation detector according to claim 7,
wherein the adhesive layer has an elastic modulus of 100 MPa or more.

12. The radiation detector according to claim 7,
wherein the adhesive layer is provided apart from the resin layer.

13. The radiation detector according to claim 1,
wherein a signal processing circuit and a terminal are provided in the peripheral region of the semiconductor layer, and
the terminal is electrically connected to the circuit board via a connection member.

14. The radiation detector according to claim 13,
wherein the detection substrate is fixed to the circuit board via an adhesive layer in the peripheral region, and
in a case where the radiation detector is seen through from a direction perpendicular to the first main surface,
an end of the adhesive layer on a side closer to the detection region has a smaller distance to the detection region than an end of the terminal on a side closer to the detection region.

15. The radiation detector according to claim 13,
wherein in a case where the radiation detector is seen through from a direction perpendicular to the first main surface,
the terminal and the circuit board overlap.

16. The radiation detector according to claim 1,
wherein in a case where the radiation detector is seen through from a direction perpendicular to the first main surface,
the circuit board is provided with an opening at a position corresponding to the detection region.

17. The radiation detector according to claim 16,
wherein a signal processing circuit and a terminal are provided in the peripheral region of the semiconductor layer, and
in a case where the radiation detector is seen through from the direction perpendicular to the first main surface,
an edge of the opening has a smaller distance from the detection region than an end of the terminal on a side closer to the detection region.

18. A radiation detector comprising:
a detection substrate including a semiconductor layer and a layer different from the semiconductor layer, and a circuit board,
wherein the detection substrate includes a detection region in which a detection element of radiation is provided in the semiconductor layer, and a peripheral region provided outside the detection region,
in at least a part of the peripheral region of the detection substrate, the circuit board supports a second main surface opposite to a first main surface of the detection substrate on which the radiation is incident,
the layer is provided in at least the detection region on at least one of the first main surface and the second main surface of the detection substrate,
a thickness of the layer in the detection region is smaller than a thickness of the semiconductor layer in the detection region, and
the layer has an elastic modulus of 100 MPa or more.

19. The radiation detector according to claim 18, wherein the layer has an elastic modulus of 300 MPa or more.

20. The radiation detector according to claim 18,
wherein the thickness of the semiconductor layer in the detection region is 10 μm or more and 100 μm or less.

21. The radiation detector according to claim 18,
wherein the thickness of the layer in the detection region is 1 μm or more and half or less of the thickness of the semiconductor layer in the detection region.

22. The radiation detector according to claim 18,
wherein the layer is provided in both the detection region and the peripheral region, and the thickness of the layer in the detection region is smaller than a thickness of the layer in the peripheral region.

23. The radiation detector according to claim 18,
wherein the layer is provided on both the first main surface and the second main surface of the detection substrate in the detection region.

24. The radiation detector according to claim 18,
wherein the detection substrate is fixed to the circuit board via an adhesive layer in the peripheral region.

25. The radiation detector according to claim 24,
wherein the adhesive layer covers at least a part of a side surface of the detection substrate.

26. The radiation detector according to claim 24,
wherein the adhesive layer includes a resin material in which metal particles are dispersed.

27. The radiation detector according to claim 24,
wherein the adhesive layer is provided apart from the layer.

28. The radiation detector according to claim 18,
wherein a signal processing circuit and a terminal are provided in the peripheral region of the semiconductor layer, and
the terminal is electrically connected to the circuit board via a connection member.

29. The radiation detector according to claim 28,
wherein the detection substrate is fixed to the circuit board via an adhesive layer in the peripheral region, and
in a case where the radiation detector is seen through from a direction perpendicular to the first main surface,
an end of the adhesive layer on a side closer to the detection region has a smaller distance to the detection region than an end of the terminal on a side closer to the detection region.

30. The radiation detector according to claim 28,
wherein in a case where the radiation detector is seen through from a direction perpendicular to the first main surface,
the terminal and the circuit board overlap.

31. The radiation detector according to claim 18,
wherein in a case where the radiation detector is seen through from a direction perpendicular to the first main surface,
the circuit board is provided with an opening at a position corresponding to the detection region.

32. The radiation detector according to claim 31,
wherein a signal processing circuit and a terminal are provided in the peripheral region of the semiconductor layer, and
in a case where the radiation detector is seen through from the direction perpendicular to the first main surface,
an edge of the opening has a smaller distance from the detection region than an end of the terminal on a side closer to the detection region.

33. A radiation imaging system comprising:
the radiation detector according to claim 1; and
a signal processing unit configured to process a signal output from the radiation detector.

34. A radiation imaging system comprising:
the radiation detector according to claim 18; and
a signal processing unit configured to process a signal output from the radiation detector.

35. A radiation imaging system comprising:
the radiation detector according to claim 1; and
a radiation source.

36. A radiation imaging system comprising:
the radiation detector according to claim 18; and
a radiation source.

37. A method for manufacturing a radiation detector, the method comprising:
preparing a semiconductor substrate in which a detection element of radiation is provided in a detection region of a first main surface and a terminal is provided in a peripheral region of the first main surface, and a circuit board;
forming a resin layer having a thickness smaller than a thickness of the semiconductor substrate in the detection region at least at a position overlapping the detection region as seen through from a direction orthogonal to the first main surface on at least one of the first main surface and a second main surface opposite to the first main surface;
fixing the semiconductor substrate on which the resin layer is formed to the circuit board such that the second main surface is supported in the peripheral region; and
electrically connecting the terminal and the circuit board with a connection member.
